(19) United States
(12) Patent Application Publication
(10) Pub. No.: US 2015/0348634 A1
(43) Pub. Date: Dec. 3, 2015

(54) SEMICONDUCTOR MEMORY DEVICE, MEMORY SYSTEM INCLUDING THE SAME, AND OPERATING METHOD THEREOF

(71) Applicant: SK hynix Inc., Gyeonggi-do (KR)

(72) Inventors: Min Gyu KOO, Gyeonggi-do (KR); Hyun HEO, Gyeonggi-do (KR); Dong Hwan LEE, Gyeonggi-do (KR)

(21) Appl. No.: 14/486,361

(22) Filed: Sep. 15, 2014

(30) Foreign Application Priority Data
May 30, 2014 (KR) 10-2014-0066448

(51) Int. Cl. G11C 16/14; G11C 16/26; G11C 16/24

(52) U.S. Cl. CPC G11C 16/14; G11C 16/24; G11C 16/26

(57) ABSTRACT

A semiconductor memory device includes a plurality of memory cells coupled between a source line and a bit line, a voltage generation circuit suitable for applying an erase voltage to the source line during an erase operation, and a read and to circuit coupled to the bit line through a selection transistor and suitable for applying an operating voltage to a first node of the selection transistor during the erase operation.

### CROSS-REFERENCE TO RELATED APPLICATION

The present application claims priority to Korean patent application number 10-2014-0066448, filed on May 30, 2014, the entire disclosure of which is incorporated herein in its entirety by reference.

### BACKGROUND

1. Field of Invention

Various exemplary embodiments of the present invention relate generally to a semiconductor memory device, a memory system including the same and an operating method thereof.

2. Description of Related Art

Semiconductor memory devices are typically categorized into volatile memory devices or non-volatile memory devices.

Volatile memory devices are considered to operate at high write and read speeds, but they are unable to retain the stored data when the power is off. Non-volatile memory devices operate at relatively low write and read speeds, but they may retain the stored data regardless of power on/off conditions. Examples of the non-volatile memory devices include Read Only Memory (ROM), Mask ROM (MROM), Programmable ROM (PROM), Erasable Programmable ROM (EPROM), Electrically Erasable and Programmable ROM (EEPROM), flash memory, Phase-change Random Access Memory (PRAM), Magnetic RAM (MRAM), Resistive RAM (RRAM) and Ferroelectric RAM (FRAM), Flash memories are categorized into NOR or NAND types.

Flash memories enjoy the advantages of both RAM and ROM. For example, flash memories may be freely programmed and erased similar to RAM. Similar to ROM, flash memories may retain the stored data even when they are not powered. Flash memories have been widely used as the storage media of portable electronic devices such as mobile phones, digital cameras, personal digital assistants (PDAs), and MP3 players.

In order to increase integration degree of semiconductor memory devices research has been conducted on semiconductor memory devices having a three-dimensional array structure. In an erase operation of a semiconductor memory device having a three-dimensional array structure, an erase voltage having a high voltage level is applied through a source line. The high voltage may be applied to a drain region of a bit line selection transistor coupled between a bit line of a memory cell array and a page buffer, causing a breakdown of the bit line selection transistor. Therefore, the size of the bit line selection transistor should be increased in consideration of such a breakdown and a punch-through phenomenon of an isolation layer.

### SUMMARY

Exemplary embodiments of the present invention are directed to a three-dimensional semiconductor memory device capable of reducing the size of a bit line selection transistor by improving characteristics thereof during an erase operation.

A semiconductor memory device according to an embodiment of the present invention may include a plurality of memory cells coupled between a source line and a bit line, a voltage generation circuit suitable for applying an erase voltage to the source line during an erase operation, and a read a id write circuit coupled to the bit line through a selection transistor and suitable for applying an operating voltage to a first node of the selection transistor during the erase operation.

A semiconductor memory device according to an embodiment of the present invention may include a plurality of memory strings coupled between respective bit lines and a common source line, a voltage generation circuit suitable for applying an erase voltage to the common source line during an erase operation, bit line selection transistors coupled to the respective bit lines, and an operating voltage applying circuit suitable for applying an operating voltage to a source region of each of the bit line selection transistors during the erase operation.

A method of operating a semiconductor memory device according to an embodiment of the present invention may include applying an erase voltage to a source line during an erase operation of a plurality of memory cells coupled between the source line and a bit line, and applying an operating voltage to a source region of a selection transistor coupled to one node of the bit line other than being coupled to the plurality of memory cells during the erase operation.

A memory system according to an embodiment of the present invention may include a semiconductor memory device including a plurality of memory cells coupled in series between a source line and a bit line and coupled to a first node of a selection transistor through the bit line, and a controller suitable for controlling the semiconductor memory device to perform an erase operation by applying an operating voltage to a second node of the selection transistor, in response to an erase command.

A semiconductor memory device according to an embodiment of the present invention may include a plurality of memory cells coupled between a source line and a bit line, read and write circuit coupled to the bit line through a bit line selection unit and suitable for reading and writing data from and to the plurality of memory cells, a voltage generation circuit suitable for applying a first voltage to the source line during an erase operation, wherein the read and write circuit applies a second voltage having a predetermined voltage difference from the first voltage to the bit line selection unit during the erase operation.

### BRIEF DESCRIPTION OF THE DRAWINGS

FIG. 1 is a block diagram illustrating a memory system including a semiconductor memory device;

FIG. 2 is a block diagram illustrating a semiconductor memory device according to an embodiment of the present invention;

FIG. 3 is a block diagram illustrating an embodiment of a memory cell array shown in FIG. 2;

FIG. 4 a three-dimensional view illustrating a memory string included in a memory block according to an embodiment of the present invention;

FIG. 5 is a circuit diagram illustrating the memory string shown in FIG. 4;

FIG. 6 is a block diagram illustrating a read and write circuit according to an embodiment of the present invention;

FIG. 7 is a block diagram illustrating a memory system including the semiconductor memory device shown in FIG. 2;

FIG. 8 is a block diagram illustrating an application example of the memory system shown in FIG. 7; and

FIG. 9 is a block diagram illustrating a computing system including the memory system shown in FIG. 8.

### DETAILED DESCRIPTION

Hereinafter various embodiments will be described in detail with reference to the accompanying drawings. The figures are provided to allow those having ordinary skill in the art to understand the scope of the embodiments of the disclosure. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, reference numerals correspond directly to the like parts in the various figures and embodiments of the present invention.

In this specification, a singular form may include a plural form as long as it is not specifically mentioned in a sentence. Furthermore, ‘include/comprise’ or ‘including/comprising’ used in the specification represents that one or more components, steps, operations, and elements exists or are added.

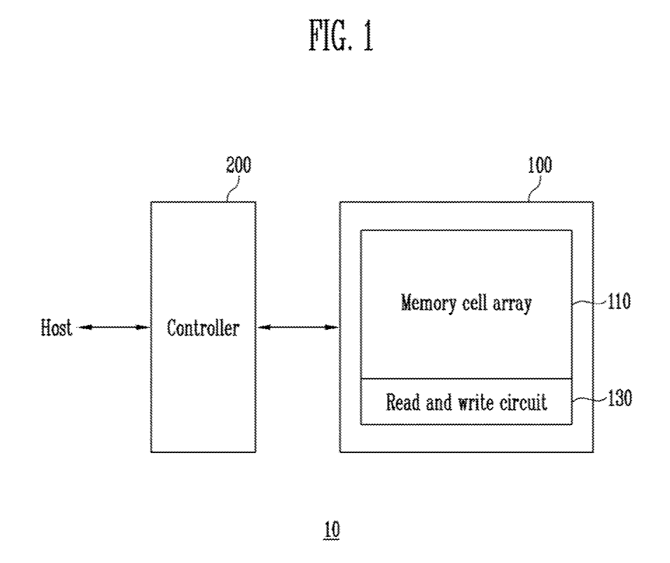

FIG. 1 is a block diagram illustrating a memory system including a semiconductor memory device.

Referring to FIG. 1, a memory system 10 may include a semiconductor memory device 100 and a controller 200. The semiconductor memory device 100 may include a memory cell array 110 and a read and write circuit 130 coupled to the memory cell array 110.

The memory cell array 110 may include a plurality of memory cells. Each of the plurality of memory cells may be defined as a multi-level memory cell which stores two or more data bits.

The semiconductor memory device 100 may operate in response to control of the controller 200. When the semiconductor memory device 100 receives an erase command from the controller 200, the semiconductor memory device 100 may be configured to perform an erase operation on memory cells (selected memory cells) in response to an address received along with the erase command. The semiconductor memory device 100 may generate an operating voltage and apply the operating voltage to source regions of selection transistors, which couple the memory cell array 110 and the read and write circuit 130, during the erase operation.

According to an embodiment, the semiconductor memory device 100 may be a flash memory device. However, the present invention is not limited to flash memory devices.

The controller 200 may be coupled between the semiconductor memory device 100 and a host. The controller 200 may be configured to interface the host and the semiconductor memory device 100. For example, at the request of the host, the controller 200 may translate a logical block address received from the host into a physical block address and provide the corresponding command and the physical block address to the semiconductor memory device 100 during the erase operation. In addition, when the erase command is inputted from the host, the controller 200 may output a command signal so that the semiconductor memory device 100 may generate an erase voltage and an operating voltage to perform the erase operation.

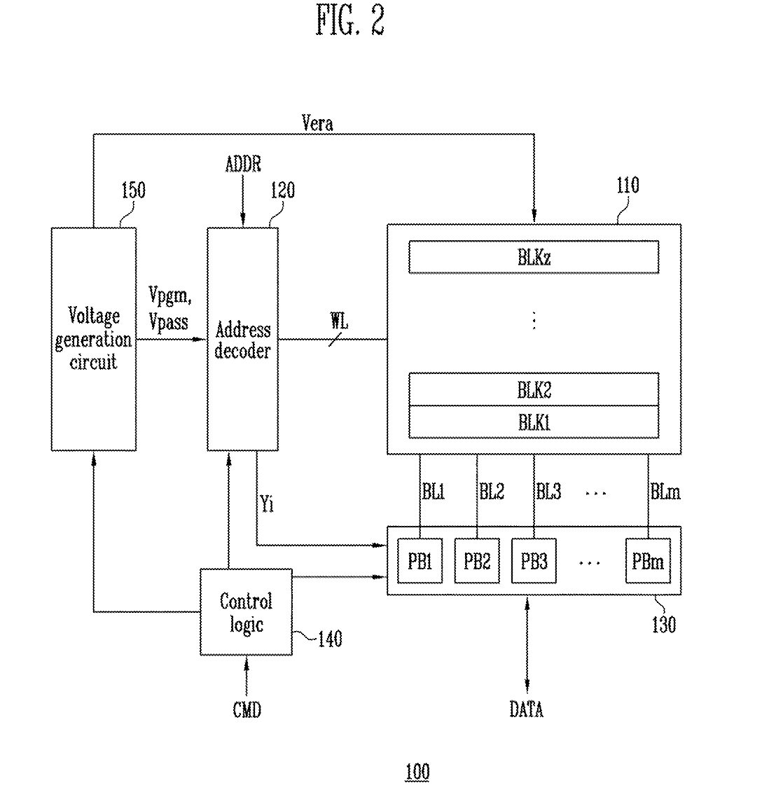

FIG. 2 is a block diagram illustrating a semiconductor memory device according to an embodiment of the present invention.

Referring to FIG. 2, the semiconductor memory device 100 may include the memory cell array 110, an address decoder 120, aread′ and write circuit 130, a control logic 140, and a voltage generation circuit 150.

The memory cell array 110 may include a plurality of memory blocks BLK1 to BLKz. The plurality of memory blocks BLK1 to BLKz may be coupled to the address decoder 120 through word lines WL. The plurality of memory blocks BLK1 to BLKz may be coupled to the read and write circuit 130 through bit lines BL1 to BLm. Each of the plurality of memory blocks BLK1 to BLKz may include a plurality of memory cells. According to an embodiment, the plurality of memory cells may be non-volatile memory cells and, more particularly, non-volatile memory cells based on charge trap devices. Memory cells coupled to the same word line may be defined as a single page. In other words, the memory cell array 110 may include a plurality of pages. In addition, each of the plurality of memory blocks BLK1 to BLKz of the memory cell array 110 may include a plurality of strings. Each of the plurality of strings may include a drain selection transistor, a plurality of drain side memory cells, a pipe transistor, a plurality of source side memory cells and a source selection transistor which are coupled in series between a bit line and a source line.

The address decoder 120, the read and write circuit 130, and the voltage generation circuit 150 may operate as a peripheral circuit which drives the memory cell array 110.

The address decoder 120 may be coupled to the memory cell array 110 through the word lines WL. The address decoder 120 may operate in response to control of the control logic 140. The address decoder 120 may receive an address ADDR through an input/output buffer (not illustrated) in the semiconductor memory device 100.

In an operation for applying a program voltage, the address decoder 120 may decode a row address of the address ADDR and apply a program voltage Vpgm and a pass voltage Vpass generated by the voltage generation circuit 150 to the plurality of word lines WL of the memory cell array 110 in response to the decoded row address.

The address decoder 120 may be configured to decode a column address of the address ADDR during a read operation. The address decoder 120 may transfer a decoded column address Yi to the read and write circuit 130.

A program operation of the semiconductor memory device 100 may be performed on each page as the basic unit. The address ADDR received upon request from the program operation may include a block address, a row address and a column address. The address decoder 120 may select a single memory block and a single word line in response to the block address and the row address. The column address may be decoded by the address decoder 120 and be provided to the read and write circuit 130. In addition, the erase operation of the semiconductor memory device 100 may be performed on each memory block as the basic unit.

The address decoder 120 may include a block decoder, a row decoder, a column decoder and an address buffer.

The read and write circuit 130 may include a plurality of page buffers PB1 to PBm. The plurality of page buffers PB1 to PBm may be coupled to the memory cell array 110 through the bit lines BL1 to BLm, respectively. The plurality of page buffers PB1 to PBm may temporarily store input data DATA and control potentials of the bit lines BL1 to BLm, respectively, in response to the temporarily stored data during the program operation. In addition, during the erase operation, the page buffers PB1 to PBm may block electrical connections by turning off bit line selection transistors and connecting them to the bit lines BL1 to BLm, respectively, and increase body effects of the bit line selection transistors by applying an operating voltage to source nodes of the bit line selection transistors. The read and write circuit 130 may operate in response to control of the control logic 140.

The control logic 140 may be coupled to the address decoder 120, the read and write circuit 130, and the voltage generation circuit 150. The control logic 140 may receive a command CMD through an input/output buffer (not illustrated) of the semiconductor memory device 100. The control logic 140 may control the general operation of the semiconductor memory device 100 in response to the command CMD.

The voltage generation circuit 150 may generate the program voltage Vpgm and the pass voltage Vpass in response to control of the control logic 140 during the program operation, and generate an erase voltage Vera in response to control of the control logic 140 during the erase operation. The erase voltage Vera generated during the erase operation may be provided to selected memory blocks, among the plurality of memory blocks BLK1 to BLKz, through the source line of the memory cell array 110.

FIG. 3 is a block diagram illustrating an embodiment of the memory cell array 110 shown in FIG. 2.

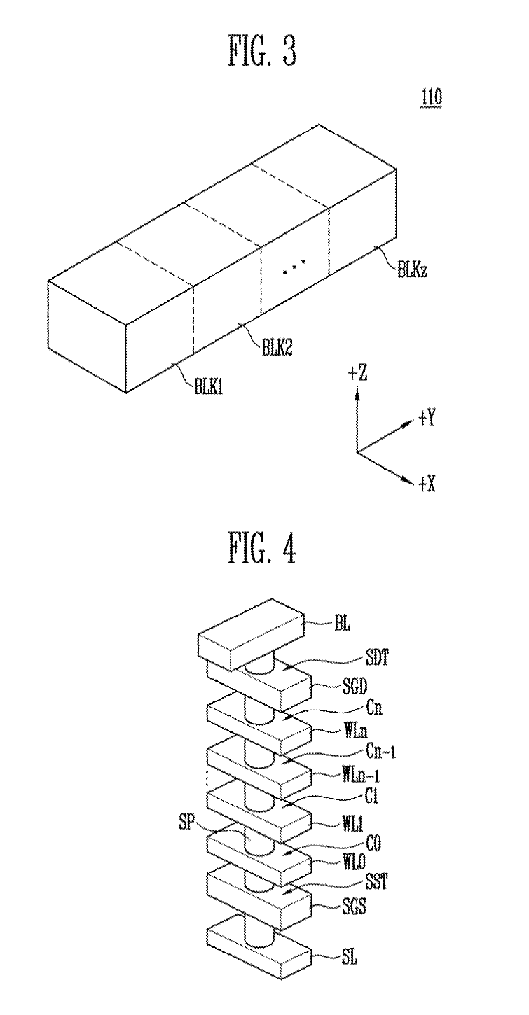

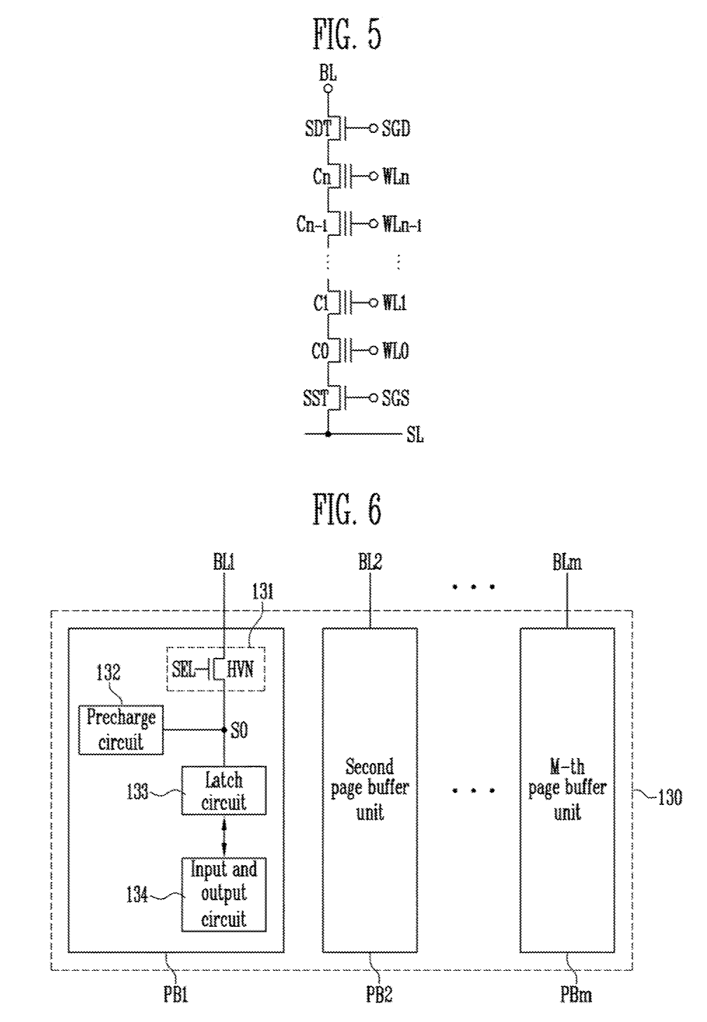

Referring to FIG. 3, the memory cell array 110 may include the plurality of memory blocks BLK1 to BLKz. Each of the memory blocks BLK1 to BLKz may have a three-dimensional structure. Each of the memory blocks BLK1 to BLKz may include a plurality of memory cells stacked over a substrate. These memory cells may be arranged in a +X direction, a +Y direction and a +Z direction, Each of the memory blocks BLK1 to BLKz will be described below in detail with reference to FIGS. 4 and 5.

FIG. 4 is a three-dimensional view illustrating a memory string included in a memory block according to an embodiment of the present invent on. FIG. 5 is a circuit diagram illustrating the memory string shown in FIG. 4.

Referring to FIGS. 4 and 5, a common source line SL may be formed over a semiconductor substrate. A vertical channel layer SP may be formed over the common source line SL. A bit line BL may be formed over the vertical channel layer SP. The vertical channel layer SP may include polysilicon. A plurality of conductive layers SGS, WL0 to WLn, and SGD may surround the vertical channel layer SP at different heights. A multilayer film (not illustrated) including a charge storage layer may be formed on a surface of the vertical channel layer SP. The multilayer film may also be formed between the vertical channel layer SP and the conductive layers SGSL, WL0 to WLn, and SGD. The multilayer film may have an ONO structure in which an oxide layer, a nitride layer and an oxide layer are stacked in a sequential manner.

The lowermost conductive layer may be a source selection line (or a first selection line) SGS, and the uppermost conductive layer may be a drain selection line (or a second selection line) SGD. The conductive layers located between the source and drain selection lines SGS and SGD may be word lines WL0 to WLn. In other words, the conductive layers SGS, WL0 to WLn, and SGD may be formed as multiple layers over the semiconductor substrate. The vertical channel layer SP passing through the conductive layers SGS, WL0 to WLn, and SGD may be coupled in a vertical direction to the semiconductor substrate between the source line SL and the bit line BL.

A drain selection transistor (or a second selection transistor) SDT may be formed where the uppermost conductive layer SGD surrounds the vertical channel layer SP. A source selection transistor (or a first selection transistor) SST may be formed where the lowermost conductive layer SGS surrounds the vertical channel layer SP. Memory cells C0 to Cn may be formed where the intermediate conductive layers WL0 to WLn surround the vertical channel layer SP.

The memory string having the above-described structure may include the source selection transistor SST, the memory cells C0 to Cn and the drain selection transistor SDT which are coupled in a vertical direction to the substrate between the common source line SL and the bit line BL. The source selection transistor SST may electrically couple the memory cells C0 to Cn to the common source line SL in response to a first selection signal applied to the first selection line SGS. The drain selection transistor SDT may electrically couple the memory cells C0 to Cn to the bit line BL in response to a second selection signal applied to the second selection line SGD.

FIG. 6 is a block diagram illustrating the read and write circuit 130 shown in FIG. 2.

Referring to FIG. 6, the read and write circuit 130 may include the plurality of page buffers PB1 to PBm. Each of the page buffers PB1 to PBm may include a bit line selection unit 131, a precharge circuit 32, a latch circuit 133 and an input/output circuit 134.

The bit line selection unit 131 may include a bit line selection transistor HVN. The bit line selection transistor HVN of the page buffer PB1 may couple a sensing node SO to the bit line BL1 in response to a bit line selection signal SEL during the program operation. In addition, the bit line selection transistor HVN may be turned off to block an electrical connection between the bit line BL1 and the sensing node SO in response to the bit line selection signal SEL during the erase operation.

The precharge circuit 132 may be coupled to the sensing node SO and precharge the sensing node SO to a predetermined potential level during the program operation. In addition, the precharge circuit; 132 may increase a potential level of a source region of the bit line selection transistor HVN in a turn-off state by applying an operating voltage greater than the predetermined potential level to the sensing node SO during the erase operation. Thus, during the erase operation, even when the erase voltage is provided to the memory string through the source line of the memory block, so that the potential level of the bit lines BL1 to BLm is increased by an erase voltage level, a body effect of the bit line selection transistor HVN having the source region to which the operating voltage greater than the predetermined potential level is applied may be increased to prevent a breakdown. Therefore, the size of bit line selection transistors HVN and the size of an isolation layer formed in the semiconductor substrate between the bit line selection transistors HVN may be reduced. In addition, when the operating voltage is applied to the source region of the bit line selection transistor HVN, a leakage current through the bit line selection transistor HVN may be effectively blocked. Even when an instantaneous current increases excessively during the erase operation, breakdown and destruction of the bit line selection transistor HVN may be prevented.

The latch circuit 133 may be coupled to the sensing node SO. The latch circuit 133 may temporarily store input data, inputted through the input/output circuit 134, and control a potential level of the sensing node SO during the program operation.

The input/output circuit 134 may transfer the input data, inputted through a data line, to the latch circuit 133 during the program operation.

An erase operation of a semiconductor memory device according to an embodiment of the present invention is described below with reference to FIGS. 2 to 6.

The voltage generation circuit 150 may generate the erase voltage Vera in response to control of the control logic 140 during the erase operation. During the erase operation, the generated erase voltage Vera may be provided to selected memory blocks, among the memory blocks BLK1 to BLKz, through the source line SL of the memory cell array 110, whereby the erase operation may be performed.

An embodiment of the erase operation is described below. First, a hole supply operation may be performed on the vertical channel layer SP of the memory string. In order to perform the hole supply operation, the word lines WL0 to WLn may be set to a floating state, and a ground voltage may be applied to the source selection line SGS. In addition, when a hole supply voltage is applied to the source line SL, holes may be supplied to the vertical channel layer by gate-induced drain leakage (GIRL) current.

After a sufficient amount of time to supply holes to vertical channel layers passes, the hole supply voltage applied to the source line SL may be changed to the erase voltage Vera. The erase voltage Vera may be greater than the hole supply voltage. The source selection line SGS may be set to a floating state. When the erase voltage Vera is applied, voltages of the source selection line SGS and the word lines WL0 to WLn in the floating state may be increased by a capacitor coupling phenomenon.

Subsequently, when a ground voltage is applied to the word lines WL0 to WLn, a voltage difference between the word lines WL0 to WLn and the vertical channel layer SP may be sufficiently increased, so that electrons trapped in the charge storage layer located between the vertical channel layer SP and the word lines WL0 to WLn may be emitted to the vertical channel layer SP.

When the erase voltage Vera is applied to the vertical channel layer SP through the source line SL, the page buffers PB1 to PBm may apply the operating voltage to source regions of the bit line selection transistors HVN having drain regions coupled to the bit lines BL1 to BLm, respectively. The operating voltage may be set to 2V or more. For example, the precharge circuit 132 may apply the operating voltage to the sensing node SO to perform the erase operation.

Therefore, even when the erase voltage Vera is applied to the memory string through the source line SL of the memory block during the erase operation, so that the potential level of the bit lines BL1 to BLm is increased by an erase voltage level, the body effect of the bit line selection transistor HVN having the source region to which the operating voltage having a predetermined potential level or more is applied may be increased to prevent a breakdown phenomenon. Therefore, the size of the bit line selection transistor HVN may be reduced.

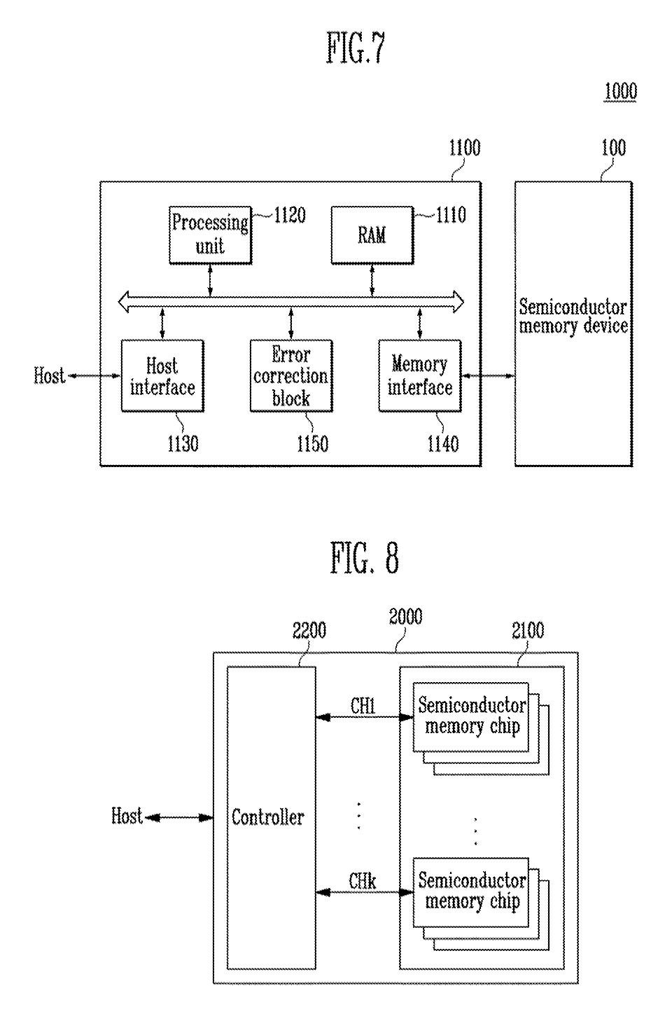

FIG. 7 is a block diagram illustrating a memory system including the semiconductor memory device shown in FIG. 2.

Referring to FIG. 7, a memory system 1000 may include the semiconductor memory device 100 and a controller 1100.

The semiconductor memory device 100 may include the semiconductor memory device described with reference to FIG. 2. Thus, a detailed description thereof will be omitted.

The controller 1100 may be coupled to a host and the semiconductor memory device 100. The controller 1100 may access the semiconductor memory device 100 at the request of the host. For example, the controller 1100 may control a read operation, a program operation, an erase operation, and/or a background operation of the semiconductor memory device 100. The controller 1100 may provide an interface between the semiconductor memory device 100 and the host. The controller 1100 may be configured to drive firmware for controlling the semiconductor memory device 100.

The controller 1100 may include a random access memory (RAM) 1110, a processing unit 1120, a host interface 1130, a memory interface 1140 and an error correction block 1150. The RAM 1100 may be used as operation memory of the processing unit 1120, a cache memory between the semiconductor memory device 100 and the host, and/or a buffer memory between the semiconductor memory device 100 and the host. The processing unit 1120 may control operations of the controller 1100. In addition, the controller 1100 may temporarily store program data provided from the host during a to operation.

The host interface 1130 may include a protocol for exchanging data between the host and the controller 1100. For example, the controller 1100 may communicate with the host through at least one of various protocols such as a universal serial bus (USB) protocol, a multimedia card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a private protocol, etc.

The memory interface 1140 may interface with the semiconductor memory device 100. For example, the memory interface may include a NAND flash interface or a NOR flash interface.

The memory system 1000 may further include an error correction block 1150. The error correction block 1150 may detect and correct errors in data read from the semiconductor memory device 100 by using an error correction code (ECC). For example, the error correction block 150 may be included in the controller 1100. The processing unit 1120 may control a read voltage in response to an error detection result of the error correction block 150 and control the semiconductor memory device 100 to perform a re-read operation.

The controller 1100 and the semiconductor memory device 100 may be integrated in one semiconductor device. For example, the controller 1100 and the semiconductor memory device 100 may be integrated in a single semiconductor device to form a memory card such as a PC card (personal computer memory card international association (PCMCIA)), a compact flash card (CF), a smart media card (SMC), a memory stick, a multimedia card (MMC, RS-MMC or MMCmicro) an SD card (SD, miniSD, micro SD or SDHC), a universal flash storage device (UFS), etc. . . .

In another example, the controller 1100 and the semiconductor memory device 100 may be integrated in a single semiconductor device to form a solid state drive (SSD). The SSD may include a storage device for storing data in a semiconductor memory device. When the memory system 1000 is used as an SSD, operational rates of the host coupled to the memory system 1000 may be significantly improved.

The memory system 1000 may be used as one of several elements in various electronic devices such as a computer, an ultra mobile PC (UMPC), a workstation, a net-book, a personal digital assistant (PDA), a portable computer, a web table, a wireless phone, a mobile phone, a smart phone, an e-book, a portable multimedia player (PMP), a portable game machine, a navigation device, a black box, a digital camera, a three-dimensional television, a digital audio recorder, a digital audio player, a digital picture recorder, a digital picture player, a digital video recorder, a digital video player, a device for transmitting/receiving information in wireless environments, devices for home networks, devices for computer networks, devices for telematics networks, an RFID device, other devices for computing systems, etc.

The semiconductor memory device 100 or the memory system 1000 may be packaged in various forms. For example, the semiconductor memory device 100 or the memory system 1000 may be packaged by various methods such as a package on package (PoP), a ball grid array (BGA), a chip scale package (CSP), a plastic leaded chip carrier (PLCC), a plastic dual in line package (PDIP), a die in waffle pack, a die in wafer form, a chip on board (COB), a ceramic dual in line package (CERDIP), a plastic metric quad flat package (MQFP), a thin quad flat package (TQFP), a small outline integrated circuit (SOIC), a shrink small outline package (SSOP), a thin small outline package (TSOP), a system in package (SIP), a multi chip package (MCP) a wafer-level fabricated package (WFP), a wafer-level processed stack package (WSP), etc.

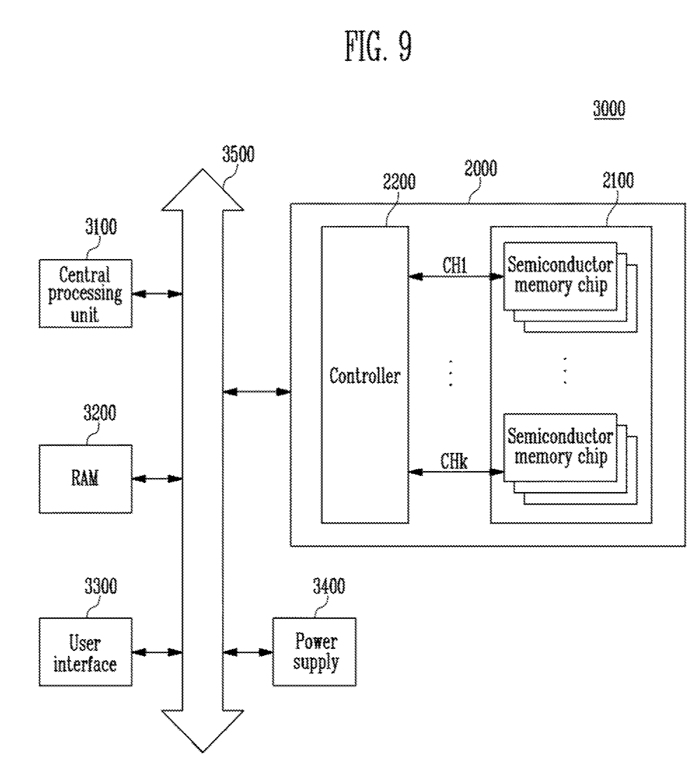

FIG. 8 is a block diagram illustrating an application example of the memory system shown in FIG. 7.

Referring to FIG. 8, a memory system 2000 may include a semiconductor memory device 2100 and a controller 2200. The semiconductor memory device 2100 may include semiconductor memory chips. The semiconductor memory chips may be divided into groups.

FIG. 8 shows the groups may communicate with the controller 2200 through first to k-th channels CH1 to CHk. Each of the semiconductor memory chips may perform the same operation as the semiconductor memory device 100 described with reference to FIG. 2.

Each group may communicate with the controller 2200 through a single common channel. The controller 2200 may be configured in the same manner as the controller 1100 described with reference to FIG. 7 and may be configured to control the plurality of memory chips of the semiconductor memory device 2100.

FIG. 9 is a block diagram illustrating a computing system 3000 having the memory system described above with reference to FIG. 8.

Referring to FIG. 9, the computing system 3000 may include a central processing unit 3100, a random access memory (RAM) 3200, a user interface 3300, a power supply 3400, a system bus 3500, and a memory system 2000.

The memory system 2000 may be electrically connected to the central processing unit 3100, the RAM 3200, the user interface 3300 and the power supply 3400 through the system bus 3500. Data provided trough the user interface 3300 or processed by the central processing unit 3100 may be stored in the memory system 2000.

In FIG. 9, the semiconductor memory device 2100 may be coupled to the system bus 3500 through the controller 2200. In some embodiments, the semiconductor memory device 2100 may be directly coupled to the system bus 3500. The central processing unit 3100 and the RAM 3200 may perform functions of the controller 2200.

As illustrated in FIG. 9, the memory system 2000 shown in FIG. 8 may be included as the memory system 3000. However, in some embodiments, the memory system 2000 may be replaced with the memory system 1000 shown in FIG. 7. In some embodiments, the computing system 3000 may include both of the memory systems 1000 and 2000 described above with reference to FIGS. 7 and 8.

According to embodiments of the present invention, since characteristics of a bit line selection transistor are improved by applying an operating voltage to a node coupled to a source region of the bit line selection transistor during an erase operation, the size of the bit line selection transistor may be reduced to improve the degree of integration of a semiconductor device.

In addition, leakage current may be effectively blocked by a bit line selection transistor. And, even when instantaneous current is excessively increased during an erase operation, breakdown and destruction of the bit line selection transistor may be prevented.

Although the inventive concept has been described with reference to a number of illustrative embodiments thereof, it should be understood that numerous other modifications and embodiments can be devised by those skilled in the art that will fall within the spirit and scope of the principles of this disclosure.

What is claimed is:

1. A semiconductor memory device, comprising:
a plurality of memory cells coupled between a source line and a bit line;
a voltage generation circuit suitable for applying an erase voltage to the source line during an erase operation; and
a read and rite circuit coupled to the bit line through a selection transistor and suitable for applying an operating voltage to a first node of the selection transistor during the erase operation.

2. The semiconductor memory device of claim 1, wherein the selection transistor is in a turn-off state to disconnect the read and write circuit from the bit line during the erase operation.

3. The semiconductor memory device of claim 1, wherein a second node of the selection transistor is coupled to the bit and a potential of the second node is increased by the erase voltage during the erase operation.

4. The semiconductor memory device of claim 1, wherein the read and write circuit includes a plurality of page buffers, and
each of the plurality of page buffers comprises:
a bit line selection unit coupled between the bit line and a sensing node and including the selection transistor; and
a precharge unit coupled to the sensing node and suitable for applying the operating voltage to the sensing node.

5. A semiconductor memory device, comprising:
a plurality of memory strings coupled between respective bit lines and a common source line;
a voltage generation circuit suitable for applying an erase voltage to the common source line during an erase operation;
bit line selection transistors coupled to the respective bit lines; and
an operating voltage applying circuit suitable for applying an operating voltage to a source region of each of the bit line selection transistors during the erase operation.

6. The semiconductor memory device of claim 5, wherein the bit line selection transistors are in a turn-off state dun the erase operation.

7. The semiconductor memory device of claim 5, wherein a potential of a drain region of each of the bit line selection transistors is increased by the erase voltage applied during the erase operation.

8. The semiconductor memory device of claim 5, wherein a body effect of each of the bit line selection transistors increased by the operating voltage applied to the source region.

9. A method of operating a semiconductor memory device, the method comprising:
applying an erase voltage to a source line during an erase operation of a plurality of memory cells coupled between the source line and a bit line; and
applying an operating voltage to a source region of a selection transistor coupled to one node of the bit line other than being coupled to the plurality of memory cells during the erase operation.

10. The method of claim 9, wherein the erase voltage is applied to a drain region of the selection transistor in the applying of the erase voltage, and the operating voltage is applied to the source region thereof in the applying of the operating voltage, thereby increasing a body effect of the selection transistor.

11. A memory system comprising:
a semiconductor memory device including a plurality of memory cells coupled in series between a source line and a bit line and coupled to a first node of a selection transistor through the bit line; and
a controller suitable for controlling the semiconductor memory device to perform an erase operation by applying an operating voltage to a second node of the selection transistor, response to an erase command.

12. The memory system of claim 11, wherein the semiconductor memory device further comprises:
a voltage generation circuit suitable for applying an erase voltage to the source line during the erase operation; and
a read and write circuit coupled to the bit line through the selection transistor and applying the operating voltage to the second node of the selection transistor during the erase operation.

13. The memory system of claim 12, wherein the selection transistor is in a turn-off state to disconnect the read and write circuit from the bit line during the erase operation.

14. The memory system of claim 12, wherein the first node of the selection transistor is coupled to the bit line, and a potential of the first node is increased by the erase voltage during the erase operation.

15. A semiconductor memory device, comprising:
a plurality of memory cells coupled between a source line and a bit line;
a read and write circuit coupled to the bit line through a bit line selection unit and suitable for reading and writing data from and to the plurality of memory cells,
a voltage generation circuit suitable for applying a first voltage to the source line during an erase operation,
wherein the read and write circuit applies a second voltage having a predetermined voltage difference from the first voltage to the bit line selection unit during the erase operation.
